(19) United States
(12) Patent Application Publication
(10) Pub. No.: US 2025/0391673 A1
(43) Pub. Date: Dec. 25, 2025

(54) SUBSTRATE CLEANING APPARATUS

(71) Applicant: SAMSUNG ELECTRONICS CO., LTD., Suwon-si (KR)

(72) Inventors: Suyoung SHIN, Suwon-si (KR); Donghoon KWON, Suwon-si (KR)

(73) Assignee: SAMSUNG ELECTRONICS CO., LTD., Suwon-si (KR)

(21) Appl. No.: 19/097,151

(22) Filed: Apr. 1, 2025

(30) Foreign Application Priority Data
Jun. 21, 2024 (KR) 10-2024-0081421

(51) Int. Cl. H01L 21/67; B08B 1/12; B08B 1/40

(52) U.S. Cl. CPC H01L 21/67046; B08B 1/12; B08B 1/40

(57) ABSTRACT

A substrate cleaning apparatus includes a core including a core body extending in a length direction and configured to rotate about a central axis extending in the length direction, a plurality of magnetic members, and a brush surrounding at least a portion of the core, the brush configured to rotate together with the core and clean a surface of a substrate, where the brush includes a magnetic portion including a magnetic material, and the magnetic portion is configured to contract in a direction toward the central axis of the core body based on a magnetic force generated by the plurality of magnetic members.

### CROSS-REFERENCE TO RELATED APPLICATION(S)

This application is based on and claims priority to Korean Patent Application No. 10-2024-0081421, filed on Jun. 21, 2024, in the Korean Intellectual Property Office, the disclosure of which is incorporated herein by reference in its entirety.

### BACKGROUND

Example embodiments of the disclosure relate to a substrate cleaning apparatus.

After a chemical mechanical polishing (CMP) process is performed for a wafer (e.g., a substrate), a cleaning process may be performed to remove particles, such as residues or organic pollutants, generated on the surface of the wafer.

The cleaning process may be conducted in a manner in which a wafer enters between roll brushes, disposed above and below the wafer. A cleaning solution is sprayed on a wafer and the roll brushes are driven to rotate in a state of touching the wafer to clean the surface of the wafer.

In related art, roll brushes may have a relatively high contact rate in the middle area of the wafer than in the edge area of the wafer, and accordingly, the brush pressure is concentrated on the middle area of the wafer, which causes the wafer damage or deterioration. In addition, as porous roll brushes hold a cleaning solution, sagging occurs in the middle portion of a roll brush by a wet condition of the load, which causes the brush pressure to be further concentrated on the middle area of the wafer.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a substrate cleaning apparatus including a brush capable of applying uniform contact pressure to a treatment target substrate.

One or more example embodiments further provide a substrate cleaning apparatus in which damage to a substrate caused by excessive contact of a brush with the substrate may be prevented while enhancing the accuracy and efficiency of substrate cleaning.

Additional aspects will be set forth in part in the description which follows and, in part, will be apparent from the description, or may be learned by practice of the presented embodiments.

According to an aspect of an example embodiment, a substrate cleaning apparatus may include a core including a core body extending in a length direction and configured to rotate about a central axis extending in the length direction, a plurality of magnetic members, and a brush surrounding at least a portion of the core, the brush configured to rotate together with the core and clean a surface of a substrate, where the brush includes a magnetic portion including a magnetic material, and the magnetic portion is configured to contract in a direction toward the central axis of the core body based on a magnetic force generated by the plurality of magnetic members.

According to an aspect of an example embodiment, a substrate cleaning apparatus may include a core body extending in a length direction and configured to rotate about a central axis extending in the length direction, a magnetic member in an area corresponding to a middle area of the core body based on the length direction, and a brush surrounding at least a portion of the core body, the brush configured to rotate together with the core body and clean a surface of a substrate, where the brush includes a magnetic portion configured to contract based on a magnetic force generated from the magnetic member and a cleaning portion on an outer surface of the magnetic portion and including a plurality of cleaning protrusions configured to contact the substrate, and where the magnetic member is spaced apart from the central axis of the core body in a direction perpendicular to the central axis of the core body.

According to an aspect of an example embodiment, a substrate cleaning apparatus may include a core including a core body extending in a length direction and configured to rotate about a central axis extending in the length direction, a plurality of magnetic members in the core, and a brush surrounding at least a portion of the core body, the brush configured to rotate together with the core body and clean a substrate, where the brush includes a magnetic portion included a magnetic material, and the magnetic portion surrounds an area where the plurality of magnetic members are in the core, and where the magnetic member is positioned so as to overlap the central axis of the core body.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view of a substrate cleaning apparatus according to one or more embodiments;

FIG. 2 is an exploded perspective view of a brush assembly included in a substrate cleaning apparatus according to one or more embodiments;

FIG. 3A is a cross-sectional view of a brush assembly according to one or more embodiments;

FIG. 3B is a cross-sectional view of the brush assembly of FIG. 3A taken along line A-A′ according to one or more embodiments;

FIG. 3C is a cross-sectional view illustrating an operation of the brush assembly of FIG. 3A according to one or more embodiments;

FIG. 4 is a cross-sectional view of a brush assembly according to one or more embodiments;

FIG. 5A is a cross-sectional view of a brush assembly according to one or more embodiments;

FIG. 5B is a cross-sectional view of the brush assembly of FIG. 5A taken along line B-B′ of FIG. 5A according to one or more embodiments;

FIG. 6 is a cross-sectional view of a brush assembly according to one or more embodiments;

FIG. 7 is a cross-sectional view of a brush assembly according to one or more embodiments;

FIG. 8 is a cross-sectional view of a brush assembly according to one or more embodiments;

FIG. 9A is a cross-sectional view of a brush assembly according to one or more embodiments;

FIG. 9B is a cross-sectional view of the brush assembly of FIG. 9A taken along line C-C′ according to one or more embodiments;

FIG. 10 is a cross-sectional view of a brush assembly according to one or more embodiments;

FIG. 11A is a cross-sectional view of a brush assembly according to one or more embodiments; and

FIG. 11B is a cross-sectional view of the brush assembly of FIG. 11A taken along line D-D′ according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, expressions such as upper side, upper portion, lower side, lower portion, side surface, front surface, and rear surface hereinafter are represented based on a direction illustrated in a drawing and may be represented otherwise when the direction of a corresponding object changes. The shape or size of elements in drawings may be exaggerated for clearer description.

Hereinafter, a substrate cleaning apparatus according to example embodiments is described with reference to the appended drawings.

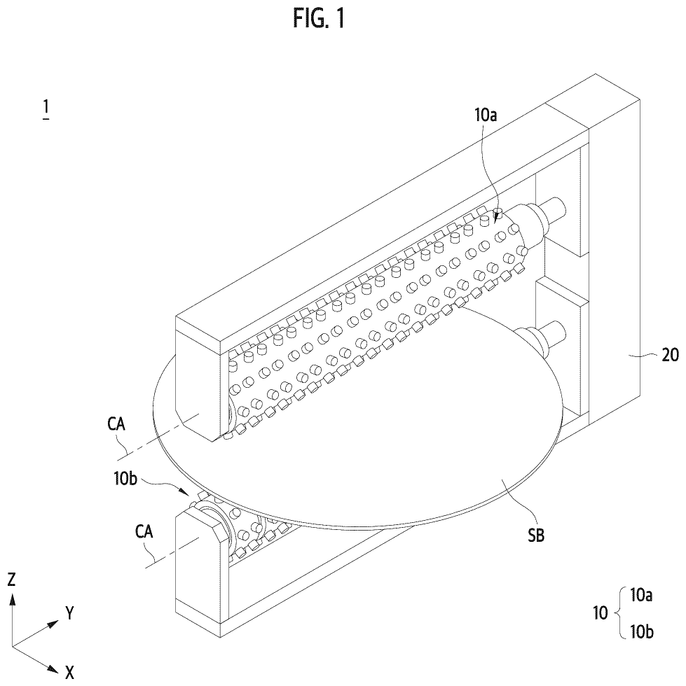

FIG. 1 is a perspective view of a substrate cleaning apparatus 1 according to one or more embodiments.

The substrate cleaning apparatus 1 according to one or more embodiments may be configured to perform a cleaning process of removing particles, such as slurry or organic pollutants, present on the surface of a wafer (e.g., a substrate) in a semiconductor fabrication process.

Referring to FIG. 1, the substrate cleaning apparatus 1 may include one or more brush assemblies 10 that clean a treatment target substrate SB, and a support frame 20 that supports the brush assemblies 10.

In one or more embodiments, the brush assemblies 10 may spray a cleaning liquid on the treatment target substrate SB and, rotate clockwise or counterclockwise about a central axis CA while contacting a surface of the treatment target substrate SB to clean the treatment target substrate SB. Various materials/solutions used for cleaning a semiconductor substrate may be applied to the cleaning liquid as will be understood by one of ordinary skill in the art from the disclosure herein.

In one or more embodiments, the substrate cleaning apparatus 1 may include a plurality of brush assemblies 10a and 10b that are configured to clean different surfaces of the treatment target substrate SB. For example, as shown in FIG. 1, the substrate cleaning apparatus 1 may include the first brush assembly 10a and the second brush assembly 10b which are disposed respectively above and below the treatment target substrate SB to clean an upper surface and a lower surface of the treatment target substrate SB.

For example, as shown in FIG. 1, the substrate cleaning apparatus 1 may include the first brush assembly 10a and the second brush assembly 10b which are disposed above and below the treatment target substrate SB to clean different surfaces of the treatment target substrate SB. The first brush assembly 10a and the second brush assembly 10b may be spaced apart by a predetermined distance, and each of the brush assemblies 10a and 10b may be driven to rotate and spray cleaning liquids with the treatment target substrate SB positioned therebetween and may clean opposite surfaces of the treatment target substrate SB. The substrate cleaning apparatus 1 may further include a substrate rotator configured to rotate the treatment target substrate SB about an axis (for example, an axis parallel with a z-axis) perpendicular to the central axis CA of the brush assemblies 10 in a cleaning process.

In one or more embodiments, the substrate cleaning apparatus 1 may further include the support frame 20 supporting the first brush assembly 10a and the second brush assembly 10b. In order to adjust for the size (for example, thickness) of the treatment target substrate SB, the first brush assembly 10a and the second brush assembly 10b may be configured to be movable in a direction closer to or farther from each other on the support frame 20 and with respect to the treatment target substrate SB. Therefore, a user may effectively clean an upper surface and a lower surface of a substrate by adjusting a distance between the first brush assembly 10a and the second brush assembly 10b in response to various sizes of substrates. However, in one or more embodiments, the substrate cleaning apparatus 1 may have one brush assembly or more than three brush assemblies 10, and an arrangement of the brush assemblies 10 may also be appropriately changed in response to the shape of the treatment target substrate SB.

In one or more embodiments, the brush assemblies 10 may be configured to partially adjust, in a length direction (y-axis direction) of the brush assemblies 10, the magnitude of pressure (hereinafter, referred to as contact pressure) which is applied as the brush assemblies 10 contact the treatment target substrate SB, an area (hereinafter, referred to as contact area) in which the brush assemblies 10 contact the treatment target substrate SB, or friction force (hereinafter, referred to as contact friction force) which is generated by such contact. For example, at least a portion of the brush assemblies 10 may be configured to be adjustable in thickness or volume. As the thickness or volume of at least a portion of the brush assemblies 10 changes, a distance between the corresponding portion of the brush assemblies 10 and the treatment target substrate SB changes, which thus may change the contact pressure and/or the contact friction force applied to the treatment target substrate SB. This change in thickness or volume of the brush assemblies 10 may be implemented by a magnetic member disposed within the brush assemblies 10 and a magnetic portion configured to adjust a thickness or volume of the brush assemblies 10 based on a magnetic force generated from the magnetic member.

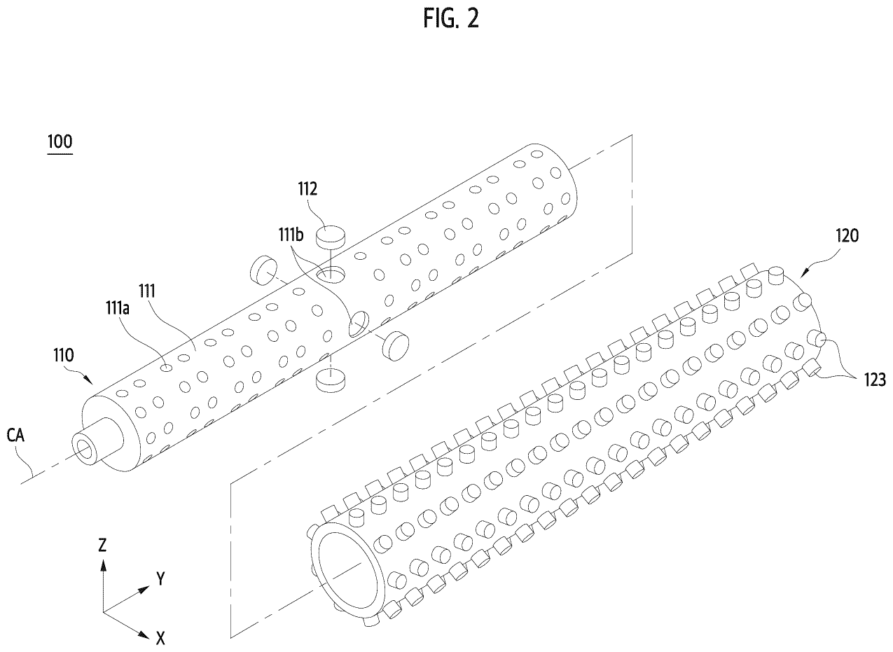

Hereinafter, with reference to FIGS. 2 to 10B, the brush assemblies 10 according to one or more embodiments including the magnetic member and the magnetic portion are described.

FIG. 2 is an exploded perspective view of a brush assembly 100 included in a substrate cleaning apparatus according to a first example embodiment.

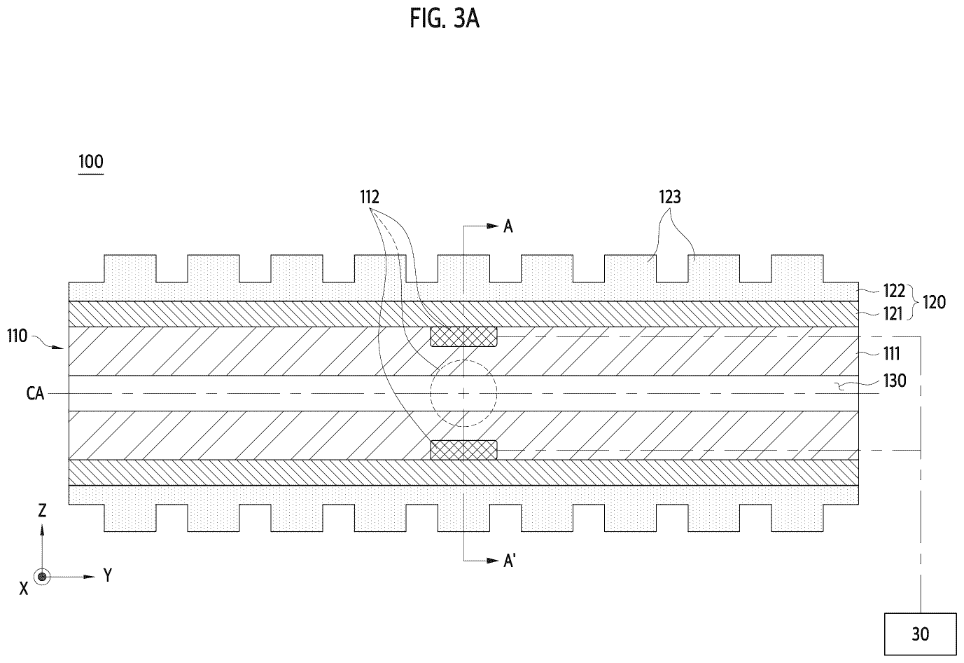

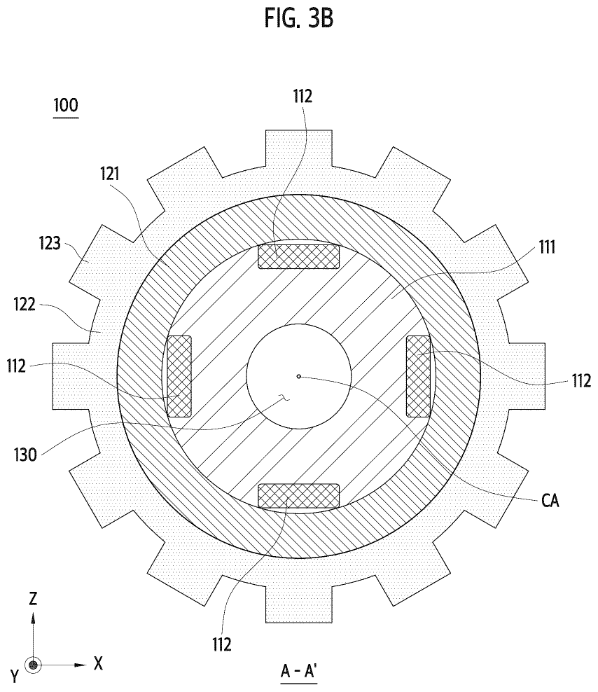

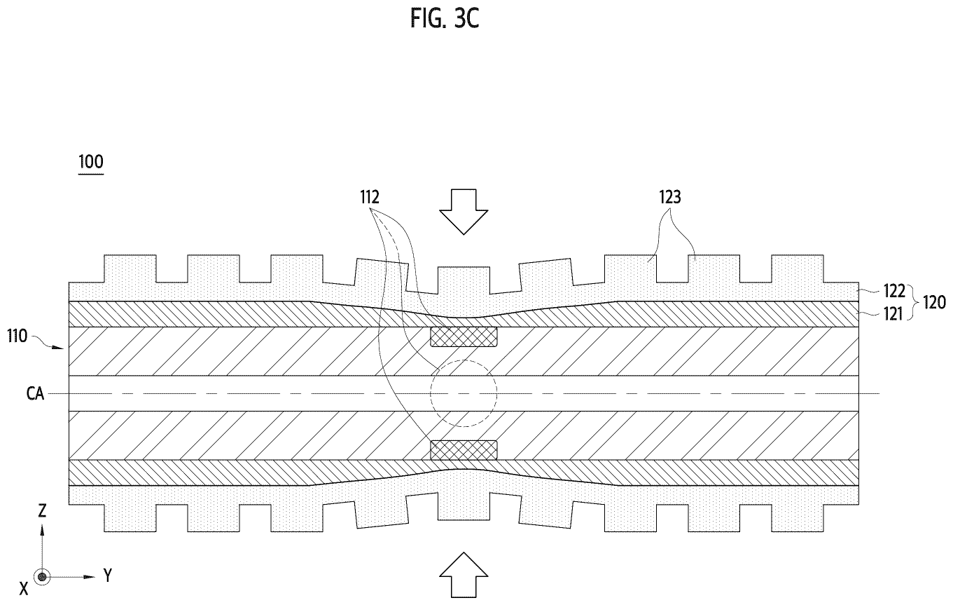

FIG. 3A is a cross-sectional view of the brush assembly 100 according to one or more embodiments.

FIG. 3B is a cross-sectional view of the brush assembly 100 taken along line A-A′ of FIG. 3A, according to one or more embodiments.

FIG. 3C is a cross-sectional view illustrating an operation of the brush assembly 100 of FIG. 3A according to one or more embodiments.

The brush assembly 100 according to one or more embodiments illustrated in FIGS. 2 to 3C features the same as or similar to those described above with respect to FIG. 1, and thus, repeated descriptions may be omitted.

Referring to FIG. 2, the brush assembly 100 may include a core 110 configured to be rotatable about the central axis CA and a brush 120, surrounding at least a portion of the core 110. The brush 120 may be configured to rotate together with the core 110 and clean a surface of a treatment target substrate (for example, treatment target substrate SB of FIG. 1).

In one or more embodiments, the core 110 may include a core body 111 that forms an overall appearance of the core 110 and a magnetic member 112 provided on the core body 111.

In one or more embodiments, the core body 111 may be a structure extending in one direction and may be configured to be rotatable about the central axis CA formed to be parallel with a length direction thereof (for example, y-axis direction). The core body 111 may have a structure such as a circular pipe or a polygonal pipe, but embodiments are not limited thereto. For example, the core body 111 may also have a structure segmented in the length direction (y-axis direction). The core body 111 may have any structure in which the brush 120 may be supported and a frame of the brush assembly 100 may be stably formed.

In one or more embodiments, a flow path 130 through which a cleaning liquid may flow may be disposed inside the core body 111. The flow path 130 may extend in the length direction (y-axis direction) of the core body 111 in a center portion of the core body 111. The cleaning liquid flowing through the flow path 130 may be sprayed outward the core body 111 through a spray hole 111a in communication with the flow path 130.

In one or more embodiments, the brush 120 disposed outside the core body 111 may rotate together with the core body 111 while holding the cleaning liquid sprayed from the core body 111 to clean particles from a surface of the treatment target substrate SB.

In one or more embodiments, the brush 120 may have a material that may hold a cleaning liquid and simultaneously provide friction force sufficient to wipe particles from the surface of the treatment target substrate SB. For example, at least a portion of the brush 120 may have porous materials. To enhance cleaning capability, a plurality of cleaning protrusions 123 may be arranged on an outer surface of the brush 120.

In one or more embodiments, the brush assembly 100 may include the magnetic member 112 coupled to the core body 111 and a magnetic portion 121. The magnetic portion 121 may be formed as a part of the brush 120, or may be formed as a separate component that is provided on the core body 111, and on which the cleaning portion 122 is provided. The magnet portion 121 may form at least a portion of the brush 120, and may be configured to contract based on a magnetic force generated from the magnetic member 112 provided on the core body 111. As the magnetic portion 121 is in at least some manner attached to the cleaning portion 122, when the magnetic portion 121 is attracted by a magnetic force generated by the magnetic member 112 of the core body 111, the cleaning portion 122 may contract in areas corresponding to the position of the magnetic members 112 of the core body 111, reducing the contact area of the middle portion of the brush 120 with the treatment target substrate SB, as is described in detail below.

Referring to FIG. 2, the magnetic member 112 may be coupled to the core 110 and configured to generate a magnetic field around the core 110. For example, the magnetic member 112 may be formed of an electromagnet from which a magnetic field is generated when a current is applied thereto. When the magnetic member 112 is formed of an electromagnet, a conducting wire connected to the magnetic member 112 may be disposed to extend in a length direction (y-axis direction) of the core 110 along the inside of the core 110. A controller 30 may control the magnitude of a current applied to the magnetic member 112 to regulate the intensity of a magnetic field generated by the magnetic member 112.

In one or more embodiments, the magnetic member 112 may be coupled to an outer surface of the core 110. For example, referring to FIG. 2, an accommodation groove 111b in which the magnetic member 112 may be accommodated may be formed on an outer surface of the core 110, and each magnetic member 112 may be accommodated in the accommodation groove 111b and fixed to the core 110.

In one or more embodiments, the magnetic member 112 may be disposed in a middle area of the core 110 based on the length direction (y-axis direction) of the core 110. For example, referring to FIGS. 3A and 3B, a plurality of magnetic members 112 may be disposed to be spaced apart in a circumferential direction based on the central axis CA in the middle area of the core 110. The plurality of magnetic members 112 may be disposed to be spaced apart from each other by similar distances. For example, referring to FIGS. 3A and 3B, four magnetic members 112 may be disposed to be rotationally symmetric based on the central axis CA. By disposing the plurality of magnetic members 112 to be rotationally symmetric, a uniform magnetic flux line distribution may be generated around the central axis CA. However, the number or position of the magnetic members 112 is not limited thereto and any suitable manner for generated a magnetic field around the core 110 may be applied for arrangement. For example, the magnetic members 112 may include three or fewer or five or more members, and distances between each other may be varied.

In one or more embodiments, the brush 120 may include the magnetic portion 121 configured to contract by a magnetic force generated from the magnetic members 112. The magnetic portion 121 may be configured to react to a magnetic field generated from the magnetic members 112 by containing a magnetic material.

In one or more embodiments, the magnetic portion 121 may form an inner surface of the brush 120 and be disposed to surround the magnetic members 112. For example, referring to FIGS. 3A and 3B, the brush 120 may include a stacked structure having a first layer that forms an inside surface of the brush 120 and include the magnetic portion 121 with strong magnetism and a second layer that forms an outside surface of the brush 120 and include a material without magnetism (or with very weak magnetism). The second layer may be a portion that directly contacts the treatment target substrate SB and may be configured to hold a cleaning liquid and clean a substrate. In The second layer portion that forms the outside surface of the brush 120 is referred to as a cleaning portion 122.

In one or more embodiments, the magnetic portion 121 may surround at least a portion of the outer surface of the core 110 and may be disposed to surround an area where the magnetic members 112 are disposed in the core 110. While FIGS. 3A to 3C show the magnetic portion 121 extending the entire length of the core 110 and the cleaning portion 122, embodiments are not limited thereto, and the magnetic portion 121 may have a smaller extension length as described below.

In one or more embodiments, the magnetic portion 121 may be configured to contract when a magnetic force is applied from the magnetic members 112, decreasing the thickness or volume of the brush assembly at areas corresponding to the magnetic members 112. The magnetic portion 121 may be configured to thereafter expand back such that the brush assembly reverts to its original thickness when the magnetic force is removed. To this end, the magnetic portion 121 may be configured to have both magnetism and elasticity.

For example, the magnetic portion 121 may be formed of a magnetic polymer that has magnetism itself and may contract in volume or thickness elastically by external force. In this case, the magnetic polymer may include a PANICNQ polymer which is a combination of emeraldine-based polyaniline (PANi) and tetracyanoquinodimethane (TCNQ). In addition, the magnetic portion 121 may also include a material in which a polymer substance without magnetism (or with very weak magnetism) such as polyvinyl acetate (PVA), polyurethane, and polyamide doped with a magnetic particle having strong magnetism. For example, the magnetic particle may be a metal particle including at least one of iron (Fe), chromium (Cr), nickel (Ni), cobalt (Co), and manganese (Mn). For example, the magnetic particle may include ferromagnetic particles such as Fe2O3, CoFe2O4, FeOFe2O3, NiOFe2O3, CuOFe2O3, MgOFe2O3, MnBi, MnSb, MnOFe2O3, Y3Fe5O12, CrO2, MnAs, and EuO. Alternatively, the magnetic portion 121 may include a material in which a magnetic polymer substance is mixed with a magnetic particle. In contrast, the cleaning portion 122 forming the second layer of the brush 120 may include a polymer material without magnetism (or with very weak magnetism) such as polyvinyl acetate (PVA), polyurethane, and polyamide.

In one or more embodiments, the magnetic portion 121 configured to have strong magnetism, elasticity, and contractility may contract in volume by a magnetic force applied from the magnetic members 112. As the volume of the magnetic portion 121 contracts, the thickness of an area where the magnetic portion 121 is disposed in the brush 120 may decrease corresponding to a contracted volume of the magnetic portion 121. For example, referring to FIG. 3C, as a magnetic field is generated from the magnetic members 112, the thickness of the magnetic portion 121 near the magnetic members 112 may decrease locally. In other words, as magnetic attraction of the magnetic members 112 is applied to the magnetic portion 121 near the magnetic members 112, a corresponding area of the magnetic portion 121 may contract in a radius direction (or a direction perpendicular to the central axis CA) of the core body 111. As the thickness of the magnetic portion 121 decreases locally, the thickness of a corresponding area of the brush 120 decreases locally, which increases a distance between this area of the brush assembly 100 and the treatment target substrate SB, which in turn may decrease the magnitude of the contact pressure or the contact friction force which the brush assembly 100 applies to the treatment target substrate SB.

For example, when a cleaning process is conducted as the brush assemblies 10 and the treatment target substrate SB are disposed horizontally as shown in FIG. 1, an edge area of the treatment target substrate SB comes into contact with the brush assembly 100 at regular time intervals according to a rotation cycle of the treatment target substrate SB, but a middle area of the treatment target substrate SB maintains a relatively constant state of contact with the brush assembly 100. As such, excessive contact between the brush assembly 100 with the treatment target substrate SB at the middle of the treatment target substrate SB) may occur (i.e., higher duration of contact and/or greater contact force). In order to prevent the treatment target substrate SB from damage by the excessive contact, the contact pressure or the contact friction force which the brush assembly 100 applies to the middle area of the treatment target substrate SB may be suitably changed. In the brush assembly 100 according to one or more embodiments, the magnetic portion 121 may contract based on a magnetic force generated from the magnetic members 112, thus decreasing the thickness or volume of a portion corresponding to the middle area of the treatment target substrate SB in the brush 120. Accordingly, since the contact pressure or the contact friction force which the brush assembly 100 applies to the middle area of the treatment target substrate SB is decreased, the damage to the treatment target substrate SB by excessive contact with a brush may be prevented.

Further, in the brush assembly 100 according to one or more embodiments the thickness of a middle area of the brush 120 may decrease and the middle area of the brush 120 may be prevented from sagging that may be caused in a wet condition due to a cleaning solution (i.e., the weight of the cleaning solution in the cleaning protrusions may cause sagging). This may allow an entire area of the brush assembly 100 to apply the contact pressure to the treatment target substrate SB at a substantially constant level. Accordingly, a cleaning capability of a substrate cleaning apparatus (for example, 1 of FIG. 1) may be maximized and fault occurrence in a treatment target substrate may be reduced.

The contraction of the magnetic portion 121 may be controlled through the controller 30. For example, the magnetic portion 121 may decrease in thickness or volume corresponding to the magnitude of a magnetic force generated from the magnetic members 112, and the controller 30 may variably regulate the thickness of the brush assembly 100 by regulating the magnitude of a current applied to the magnetic members 112. When the magnitude of the magnetic force generated from the magnetic members 112 increases, a contracted volume of the magnetic portion 121 may increase and a thickness of the brush 120 may decrease in response thereto. Conversely, when the magnitude of the magnetic force generated from the magnetic members 112 decreases, a contracted volume of the magnetic portion 121 may increase and a thickness of the brush 120 may decrease in response thereto. Thus, the controller 30 may change the magnitude of the contact pressure or the contact friction force which the brush assembly 100 applies to the treatment target substrate SB by regulating the intensity of the magnetic force generated from the magnetic members 112.

In one or more embodiments, the size of each magnetic member 112 may be variously formed. For example, any one magnetic member 112 may be a coin-shaped member with about a 5 centimeter (cm) radius and about a 2 cm height and may be arranged as an electromagnet in which a coil of about a 10 ampere (A) current flowing is wound about 1000 times. However, the size of a magnetic member or the number of times that a coil is wound are not limited thereto. For example, depending on a degree of elasticity of a material composing a magnetic portion 121, the size of a magnetic member 112 may be formed to be larger than or smaller than the that described above, and the number of times that a coil is wound may also be changed in various manners. In other words, a magnetic member 112 may be implemented in any size or structure that may contract a magnetic portion 121 suitably. In addition, when needed, a plurality of magnetic members may be configured to have different sizes or appearances.

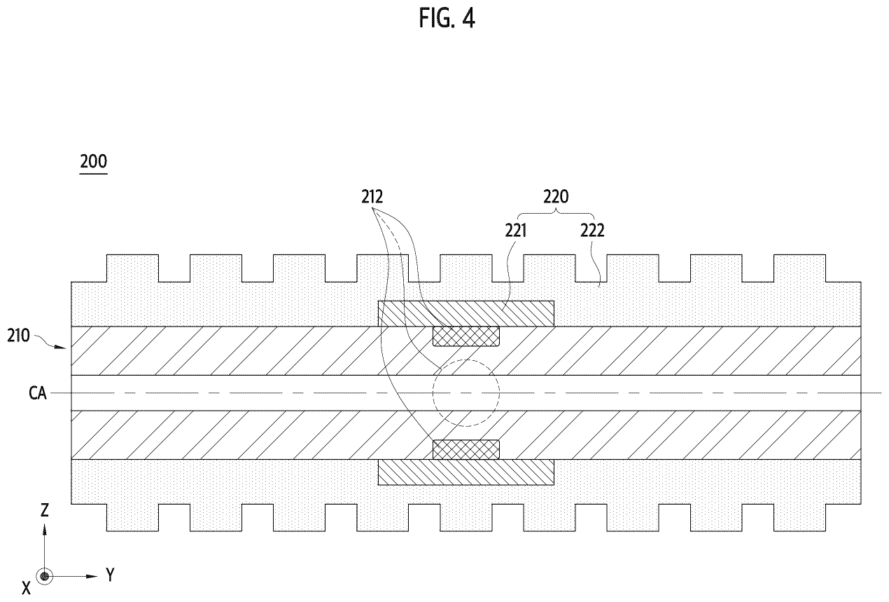

In one or more embodiments, a magnetic portion of a brush assembly may also be formed in a middle area of an inner surface of a brush. Hereinafter, with reference to FIGS. 4 to 11B, a brush assembly according to one or more embodiments is described. Description of aspects the same as or similar to those described above may be omitted. For example, all of the configuration of the individual magnetic member 112, the material feature of the magnetic portion 121, and the controller 30 described above may also be applied to the brush assembly according to the embodiments of FIGS. 4 to 11B.

FIG. 4 is a cross-sectional view of the brush assembly 200 according to one or more embodiments.

The brush assembly 200 according to one or more embodiments may include a core 210 to which magnetic members 212 are coupled and a brush 220, surrounding the core 210, in which a magnetic portion 221 is disposed.

In one or more embodiments, the magnetic portion 221 may be provided in a middle area of a length direction (y-axis direction) in an inner surface of the brush 220. For example, referring to FIG. 4, the magnetic members 212 may be disposed in the middle of the core 210, and the magnetic portion 221 may be disposed to face the magnetic members 212.

In the brush 220, by disposing the magnetic portion 221 with strong magnetism in a local area corresponding to positions of the magnetic members 212 and forming remaining areas including a cleaning portion 222 from general polymer substances such as PVA, polyurethane, and polyamide (i.e., relatively weak magnetism), the brush 220 with sufficient magnetism in the middle area to reduce fabrication costs and regulate thickness may be fabricated.

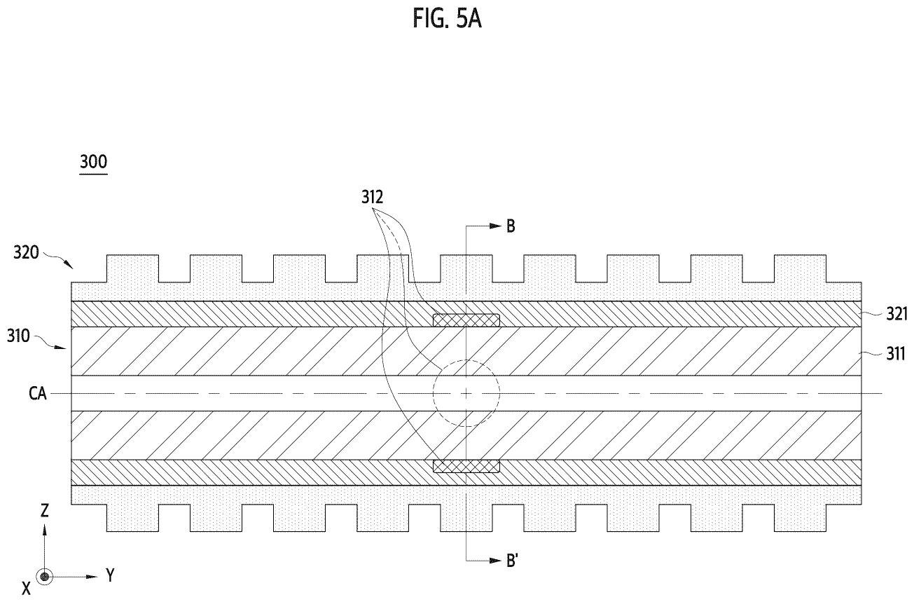

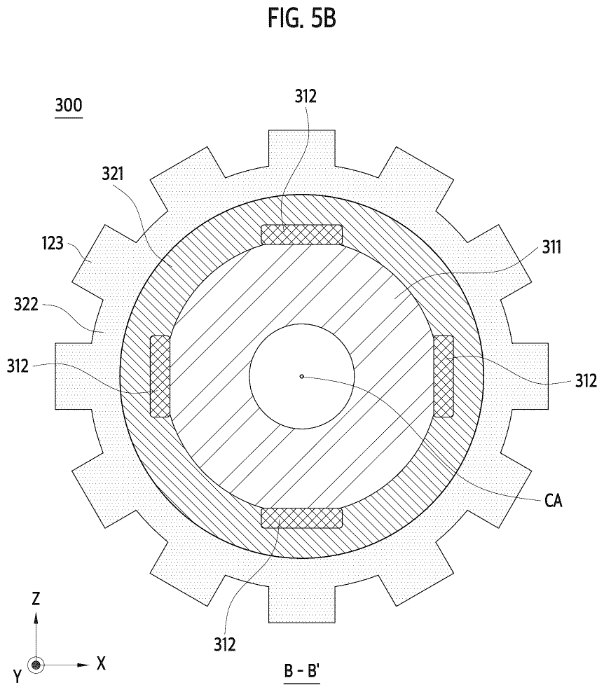

FIG. 5A is a cross-sectional view of a brush assembly 300 according to one or more embodiments.

FIG. 5B is a cross-sectional view of the brush assembly 300 taken along line B-B′ of FIG. 5A according to one or more embodiments.

The brush assembly 300 according to one or more embodiments may include a core 310 to which magnetic members 312 are coupled and a brush 320, surrounding the core 310, in which a magnetic portion 321 is disposed, and the magnetic members 312 may be disposed outside a core body 311. For example, referring to FIGS. 5A and 5B, each of the magnetic members 312 may be disposed such that the magnetic members 312 contact an outer surface of the core body 311, and the remaining outer surface of the core body 311 may be contacted by the magnetic portion 321. In this case, the magnetic portion 321 may be formed to surround all the surfaces of the core body 311 excluding the surface of core body 311 that is contacted by the magnetic members 312.

Since an area in which the magnetic members 312 are exposed to the magnetic portion 321 may be maximized, the magnetic members 312 may regulate a change in thickness or volume of the magnetic portion 321 more easily, and accordingly, the magnitude of the contact pressure or the contact friction force which a cleaning portion 322 applies to the treatment target substrate SB may be easily regulated.

In one or more embodiments, based on a radius direction to the central axis CA, the thickness of the magnetic portion 321 may be greater than the thickness of the magnetic members 312. In addition, the portion of the magnetic portion 321 that covers the magnetic members 312 may be the equal to or greater than the thickness of the magnetic members 312, thereby allowing for a desired sufficiency of contraction to occur. However, the thickness of the magnetic portion 321 is not limited thereto and may vary.

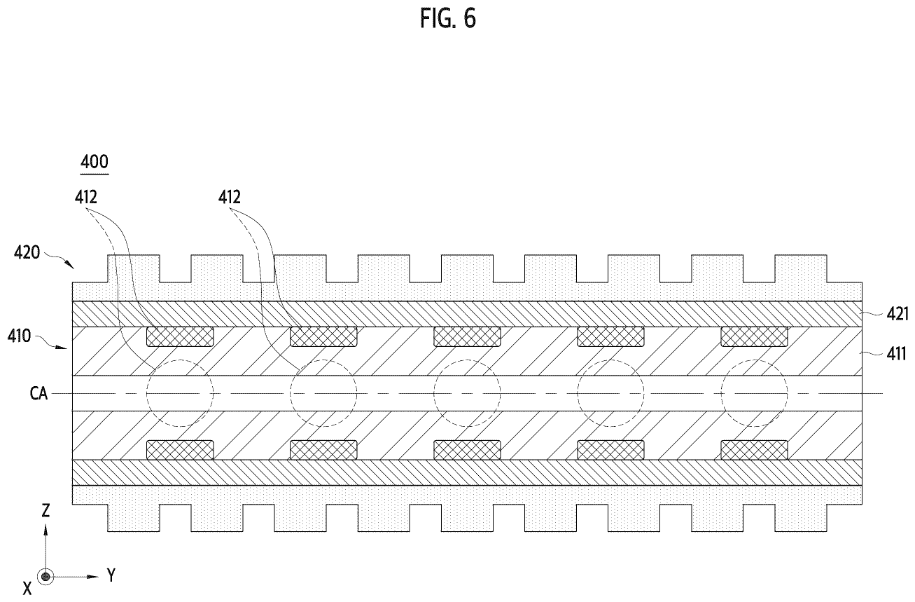

FIG. 6 is a cross-sectional view of a brush assembly 400 according to one or more embodiments.

The brush assembly 400 according to one or more embodiments may include a core 410 to which magnetic members 412 are coupled and a brush 420, surrounding the core 410, in which a magnetic portion 421 is disposed. The magnetic members 412 may be circumferentially arranged in a plurality of groups along the length direction of the core body 411. For example, referring to FIG. 6, four magnetic members 412 may be disposed in a circumferential direction based on the central axis CA of the core body 411 to form one group of the magnetic members 412, and the plurality of groups of the magnetic members 412 may be disposed to be spaced apart from each other in a direction parallel to the central axis CA of the core body 411. The magnetic portion 421 of the brush 420 may form an inner surface of the brush 420 and disposed to face the plurality of groups of the magnetic members 412 in a direction perpendicular to the central axis CA of the core body 411.

As the plurality of groups of the magnetic members 412 are disposed in the length direction (y-axis direction) of the core body 411, the thickness or volume of the brush 420 may be regulated locally in multiple areas of the brush assembly 400. For example, when decreasing friction with the treatment target substrate SB in a middle area of the brush assembly 400, the volume of the brush 420 may be partially reduced by applying a current to a group of the magnetic members 412 corresponding to a middle area. Alternatively, when brush sagging frequently occurs in a specific area of the brush assembly 400, the sagging of the brush 420 may be prevented by applying a current to a group of the magnetic members 412 corresponding to a sagging area. Thus, the thickness of the brush assembly may be variously controlled in middle areas, edge areas, and combinations thereof, based on the groups of the plurality of magnetic members 412.

In one or more embodiments, a controller (for example, 30 of FIG. 3A) may be configured to control the plurality of groups of the magnetic members 412 independently of each other. For example, the controller 30 may individually control the magnitude of currents applied to some of the plurality of groups of the magnetic members 412 and a specific magnetic member in one group of the magnetic members 412, and accordingly, a degree of freedom of regulating the thickness or volume of the brush 420 may be increased.

The magnetic portion 421 in the brush assembly 400 according to one or more embodiments may also be formed to correspond to areas where the magnetic members 412 are located. That is, the structure shown in FIGS. 5A and 5B may be combined with the structure shown in FIG. 6, such that the magnetic portion 421 is partitioned with sections that each correspond to locations of the groups of magnetic members 412.

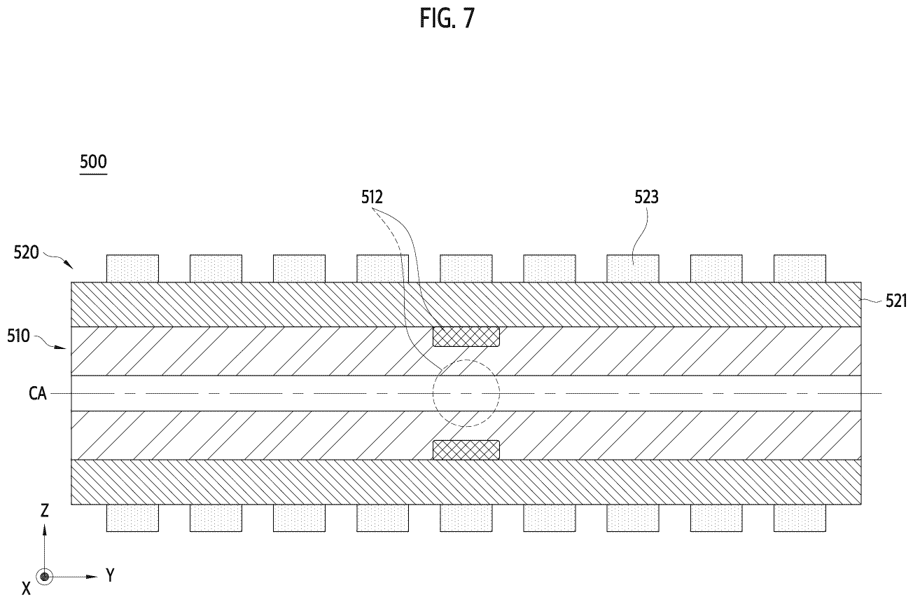

FIG. 7 is a cross-sectional view of a brush assembly 500 according to one or more embodiments.

The brush assembly 500 according to one or more embodiments may include a core 510 to which magnetic members 512 are coupled and a brush 520, surrounding the core 510, in which a magnetic portion 521 is disposed. As shown in FIG. 7, and as opposed to that shown in, for example, FIG. 3A, a non-magnetic cleaning portion is omitted, and the magnetic portion 521 is mainly applied, such that the cleaning protrusions 523 are formed directly on the magnetic portion 5521. In this case, the cleaning protrusions 523 may be formed of general polymer substances such as PVA, polyurethane, and polyamide without magnetism (or with very weak magnetism).

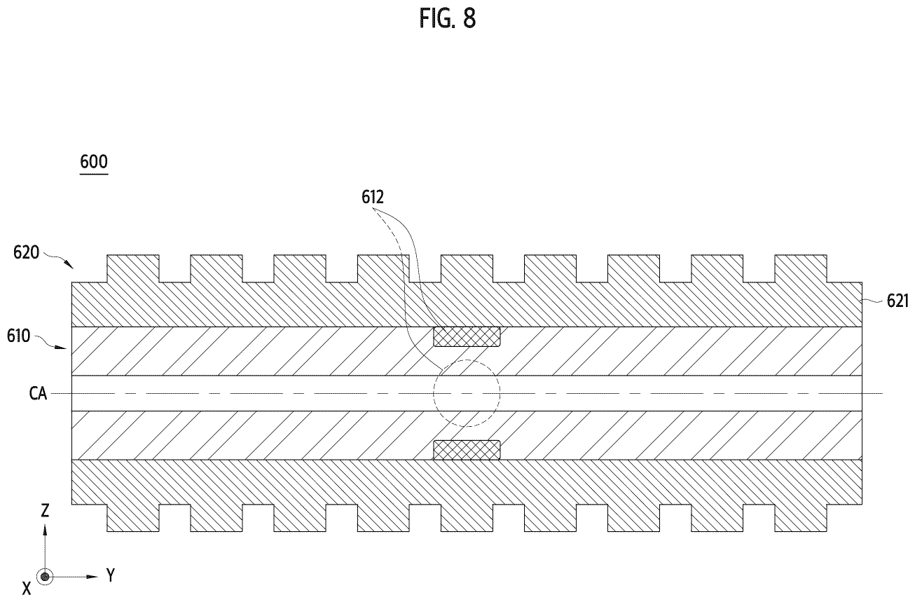

FIG. 8 is a cross-sectional view of a brush assembly 600 according to one or more embodiments.

The brush assembly 600 according to one or more embodiments may include a core 610 to which magnetic members 612 are coupled and a brush 620, surrounding the core 610, in which a magnetic portion 621 is disposed, and the brush 620 may be all formed as the magnetic portion 621 with magnetism.

When a portion with magnetism is formed to be broad in the brushes 520 and 620, a greater range of volume changes of the brushes 520 and 620 (i.e., larger range of contraction and expansion) by the magnetic force of the magnetic members 512 and 612 may be formed.

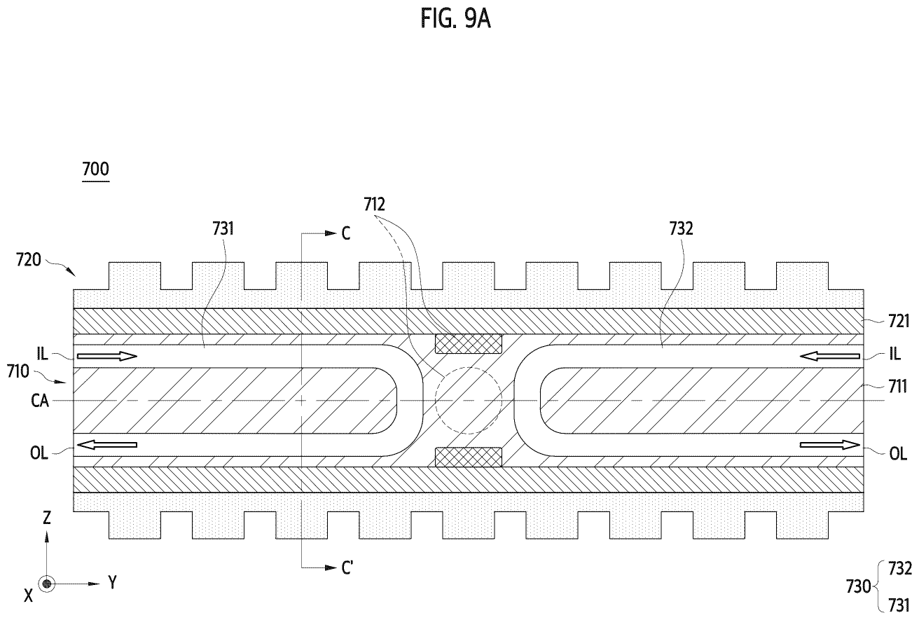

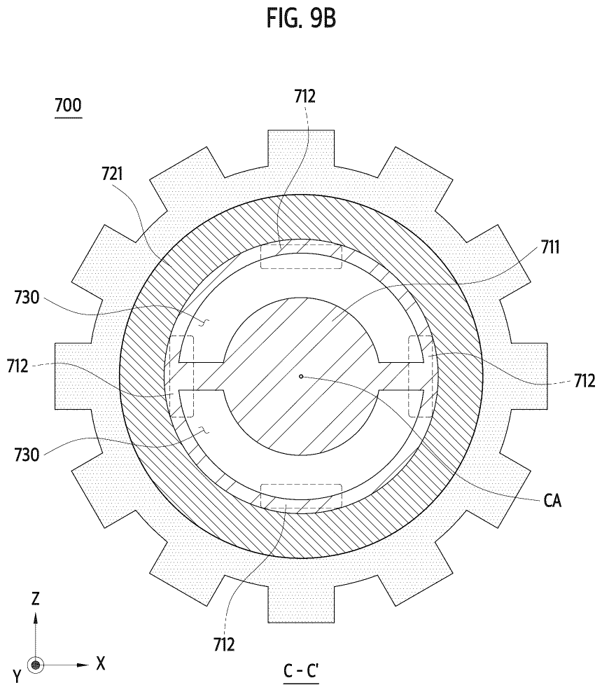

FIG. 9A is a cross-sectional view of a brush assembly 700 according to one or more embodiments.

FIG. 9B is a cross-sectional view of the brush assembly 700 taken along line C-C′ of FIG. 9A, according to one or more embodiments.

In one or more embodiments, the brush assembly 700 may include a core 710 to which magnetic members 712 are coupled and a brush 720, surrounding the core 710, in which a magnetic portion 721 is disposed and may include a plurality of flow paths 730 formed to be divided at opposite sides of a core body 711 based on the position of the magnetic members 712.

For example, referring to FIG. 9A, the brush assembly 700 may include a first flow path 731 into which a cleaning liquid is introduced from a first side of the core body 711 and is expelled from the first side of the core body 711 and a second flow path 732 into which a cleaning liquid is introduced from a second side of the core body 711 and is expelled from the second side of the core body 711. Referring to FIGS. 9A and 9B together, while a cleaning liquid flows inside the flow paths 730 after being introduced through an inlet IL disposed in one side end portion of the core body 711, a portion thereof may be provided to the brush 720 and the other portion thereof may be released through an outlet OL formed at the end portion where the inlet IL is positioned. By positioning the two separate flow paths 731 and 732, different types of cleaning liquids may also be supplied to each flow path 731 and 732 to clean the treatment target substrate SB.

In one or more embodiments, the first flow path 731 and the second flow path 732 may be disposed to be spaced apart from each other with a middle area where the magnetic members 712 are disposed in the core body 711 therebetween. In other words, as illustrated in FIG. 9A, each of the plurality of flow paths 730 may be disposed to avoid areas where the magnetic members 712 are disposed, and a cleaning liquid flowing inside the first flow path 731 may be sprayed to a left area of the brush 720 and a cleaning liquid flowing inside the second flow path 732 may be sprayed to a right area of the brush 720.

By separating an area where the magnetic members 712 are disposed based on a length direction (y-axis direction) of the brush assembly 700 and an area where a cleaning liquid flows, mutual interferences may be prevented from occurring between the magnetic members 712 and the cleaning liquid, and the diameter of the flow paths 730 and the size of the magnetic members 712 may be formed to be greater.

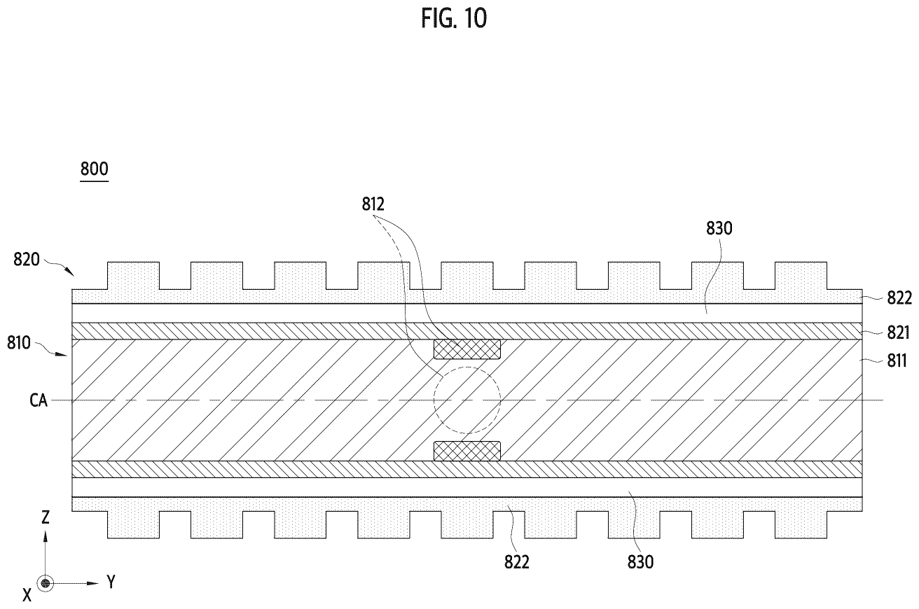

FIG. 10 is a cross-sectional view of a brush assembly 800 according to one or more embodiments.

In one or more embodiments, the brush assembly 800 may include a core 810 to which magnetic members 812 are coupled and a brush 820, surrounding the core 810, in which a magnetic portion 821 is disposed and may include a flow path 830 formed inside the brush 820.

Referring to FIG. 10, the flow path 830 may be disposed between the magnetic portion 821 and a cleaning portion 822 in the brush 820. Here, the cleaning portion 822 may be a portion formed of general polymer substances such as PVA, polyurethane, and polyamide without magnetism (or with very weak magnetism).

By positioning the flow path 830 inside the brush 820 thus, a cleaning liquid may be supplied directly to the brush 820. In addition, since the flow path 830 is omitted from a core body 811, the larger magnetic members 812 may be disposed and a degree of freedom of arranging the magnetic members 812 may also be increased.

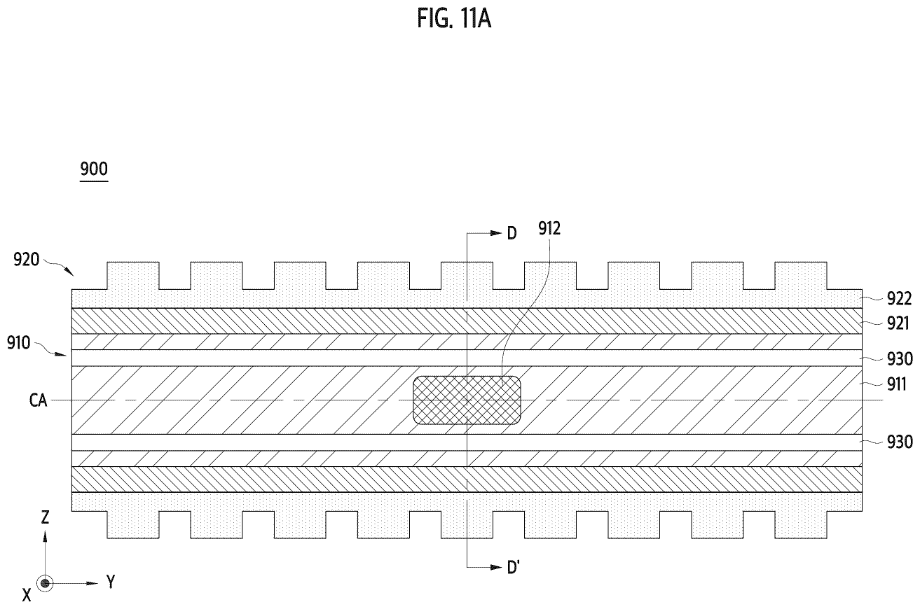

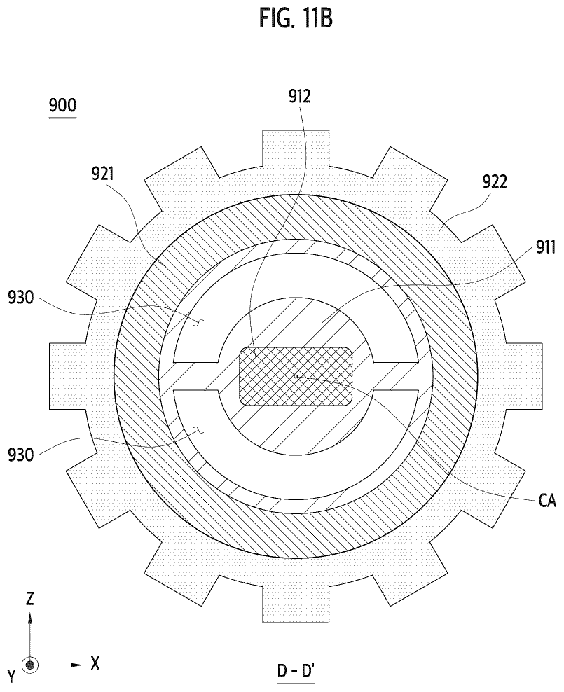

FIG. 11A is a cross-sectional view of a brush assembly 900 according to one or more embodiments.

FIG. 11B is a cross-sectional view of the brush assembly 900 taken along line D-D′ of FIG. 11A according to one or more embodiments.

In one or more embodiments, the brush assembly 900 may include a core 910 to which a magnetic member 912 is coupled and a brush 920, surrounding the core 910, in which a magnetic portion 921 and a cleaning portion 922 are disposed, and the magnetic member 912 of the brush assembly 900 may be disposed inside the core 910 (i.e., the central axis CA of the core 910 may pass through the magnetic member 912). For example, referring to FIGS. 11A and 11B, the single magnetic member 912 that may generate a strong magnetic field may be disposed inside a core body 911. However, the magnetic member 912 may be arranged as a plurality of magnetic members in a length direction (y-axis direction) of the core 910 inside the core 910 or may also be arranged in a circumferential direction based on the central axis CA inside the core 910. Alternatively, the magnetic member may have a toroidal structure surrounding an outer surface of the core 910.

In one or more embodiments, flow paths 930 of the brush assembly 900 may be disposed to avoid the magnetic member 912. For example, referring to FIGS. 11A and 11B, inside the core body 911, a plurality of flow paths 930 through which a cleaning liquid may flow may extend in a direction parallel to the central axis CA with the magnetic member 912 therebetween. In other words, the plurality of flow paths 930 may be disposed between the magnetic member 912 and an outer surface of the core body 911.

However, in one or more embodiments, the arrangement of the flow path 930 is not limited thereto. For example, in one or more embodiments, the flow paths 930 may be disposed to contact at least a portion of the magnetic member 912. Accordingly, a cleaning liquid flowing inside the flow paths 930 may contact at least a portion of the magnetic member 912. Based on the magnetic member 912, since the intensity of a magnetic field inside water is not much different from the intensity of a magnetic field inside air or vacuum, a decrease in thickness or volume of the magnetic portion 121 may identically occur even though the magnetic member 912 is exposed to the cleaning liquid. Alternatively, in one or more embodiments, the flow path 930 may be formed to be divided at one side and another side in a direction of the central axis CA based on the magnetic member like the flow paths 731 and 732 illustrated in FIG. 9A.

In one or more embodiments, the magnetic portion 921 and the cleaning portion 922 may corresponds to those described above with reference to FIGS. 1 to 10. For example, in one or more embodiments, the brush 920 overall may also include the magnetic portion with magnetism.

As described above, the substrate cleaning apparatus 1 according to one or more embodiments may include a brush assembly in which a volume or a thickness may decrease locally and thus may regulate contact pressure or contact friction force which the brush assembly applies to the treatment target substrate SB. Accordingly, the substrate cleaning apparatus 1 according to one or more embodiments may allow the contact pressure that the brush assembly applies in a substrate cleaning process to be formed evenly throughout an entire area of the treatment target substrate SB. In other words, when a specific area of the brush assembly cleans the treatment target substrate SB with a stronger contact pressure than another area (i.e., a middle area versus an edge area), or when a time in which a specific area of the brush assembly is in contact with the treatment target substrate SB is maintained as longer than a suitable level, the thickness or volume of a portion corresponding to the specific area may be decreased locally, which thus may lead the entire area of the brush assembly to apply the contact pressure of the consistent level to the treatment target substrate SB. Accordingly, a specific area of the treatment target substrate SB may be prevented from deteriorating due to intensively applied strong contact pressure in a cleaning process.

In addition, according to the substrate cleaning apparatus 1 in one or more embodiments, the contact area in which a specific area of the treatment target substrate SB is contacted in the brush assembly and contact pressure may be regulated finely to the user-configured magnitude. Accordingly, since the treatment target substrate SB may be cleaned in different intensities for each area, a cleaning capability of the substrate cleaning apparatus 1 may be maximized and fault occurrence in the treatment target substrate may be reduced.

According to one or more embodiments, a substrate cleaning apparatus may be implemented that applies uniform contact pressure to a treatment target substrate using a segmented-type brush assembly.

In addition, according to one or more embodiments, a substrate cleaning apparatus may be provided in which a substrate may be prevented from damage by excessive contact of a brush with the substrate while enhancing the accuracy and efficiency of substrate cleaning.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A substrate cleaning apparatus comprising:
a core comprising a core body extending in a length direction and configured to rotate about a central axis extending in the length direction;
a plurality of magnetic members; and
a brush surrounding at least a portion of the core, the brush configured to rotate together with the core and clean a surface of a substrate,
wherein the brush comprises a magnetic portion comprising a magnetic material, and
wherein the magnetic portion is configured to contract in a direction toward the central axis of the core body based on a magnetic force generated by the plurality of magnetic members.

2. The substrate cleaning apparatus of claim 1, wherein the magnetic portion faces the plurality of magnetic members in a direction perpendicular to the central axis of the core body.

3. The substrate cleaning apparatus of claim 1, wherein the plurality of magnetic members are spaced apart in a circumferential direction with respect to the central axis of the core body.

4. The substrate cleaning apparatus of claim 3, wherein the plurality of magnetic members are provided in an area corresponding to a middle area of the core body based on the length direction of the core body.

5. The substrate cleaning apparatus of claim 4, wherein the core further comprises:
a first flow path configured to introduce a cleaning liquid from a first side of the core body and expel the cleaning liquid from the first side of the core body; and
a second flow path configured to introduce a cleaning liquid from a second side of the core body and expel the cleaning liquid from the second side of the core body, and
wherein, in the length direction of the core body, the plurality of magnetic members are between the first flow path and the second flow path.

6. The substrate cleaning apparatus of claim 1, wherein some of the plurality of magnetic members are arranged in a circumferential direction based on the central axis of the core body to form a group of magnetic members, and
wherein a plurality of groups of magnetic members are formed in a direction parallel to the central axis of the core body.

7. The substrate cleaning apparatus of claim 1, wherein the plurality of magnetic members are provided on an outer surface of the core body.

8. The substrate cleaning apparatus of claim 7, wherein the plurality of magnetic members are respectively accommodated in a plurality of grooves that are on the outer surface of the core body.

9. The substrate cleaning apparatus of claim 1, wherein at least one magnetic member among the plurality of magnetic members has a first surface contacting an outer surface of the core body, and
wherein a second surface of the at least one magnetic member is exposed to the magnetic portion.

10. The substrate cleaning apparatus of claim 1, wherein the brush further comprises a cleaning portion on an outer surface of the magnetic portion,
wherein the cleaning portion comprises a plurality of cleaning protrusions configured to contact the substrate, and
wherein the magnetic portion comprises a material that is different from a material of the cleaning portion.

11. The substrate cleaning apparatus of claim 10, wherein the brush further comprises a flow path between the cleaning portion and the magnetic portion and configured to introduce a cleaning liquid into the brush.

12. The substrate cleaning apparatus of claim 1, wherein the magnetic portion comprises a cleaning portion comprising a plurality of cleaning protrusions.

13. The substrate cleaning apparatus of claim 1, wherein the magnetic material comprises a magnetic polymer or a magnetic particle,
wherein the magnetic polymer comprises a PANICNQ polymer, and
wherein the magnetic particle comprises a metal particle comprising at least one of iron (Fe), chromium (Cr), nickel (Ni), cobalt (Co), and manganese (Mn).

14. The substrate cleaning apparatus of claim 1, wherein the plurality of magnetic members comprise electromagnets in which a magnetic field is generated based on an applied current, and
wherein the substrate cleaning apparatus further comprises a controller configured to control a magnitude of the current applied to the plurality of magnetic members.

15. A substrate cleaning apparatus comprising:
a core body extending in a length direction and configured to rotate about a central axis extending in the length direction;
a magnetic member in an area corresponding to a middle area of the core body based on the length direction; and
a brush surrounding at least a portion of the core body, the brush configured to rotate together with the core body and clean a surface of a substrate,
wherein the brush comprises:
a magnetic portion configured to contract based on a magnetic force generated from the magnetic member; and
a cleaning portion on an outer surface of the magnetic portion and comprising a plurality of cleaning protrusions configured to contact the substrate, and
wherein the magnetic member is positioned so as to overlap the central axis of the core body.

16. The substrate cleaning apparatus of claim 15, further comprising a plurality of flow paths in the core body and configured to introduce a cleaning liquid to the brush,
wherein the magnetic member is between the plurality of flow paths.

17. A substrate cleaning apparatus comprising:
a core comprising a core body extending in a length direction and configured to rotate about a central axis extending in the length direction;
a plurality of magnetic members in the core; and
a brush surrounding at least a portion of the core body, the brush configured to rotate together with the core body and clean a substrate,
wherein the brush comprises a magnetic portion comprising a magnetic material, and
wherein the magnetic portion surrounds an area where the plurality of magnetic members are in the core.

18. The substrate cleaning apparatus of claim 17, wherein the plurality of magnetic members are rotationally symmetric about the central axis of the core body.

19. The substrate cleaning apparatus of claim 17, wherein the magnetic portion is configured to contract based on a magnetic force generated by the plurality of magnetic members.

20. The substrate cleaning apparatus of claim 17, wherein the brush further comprises:
a first layer comprises the magnetic portion; and
a second layer outside the first layer and comprises a polymer material configured to receive a cleaning liquid.
